(19) United States
(12) Patent Application Publication
(10) Pub. No.: US 2005/0127444 A1
(43) Pub. Date: Jun. 16, 2005

(54) Semiconductor integrated circuit

(76) Inventor: Junichiro Watanabe, Yokohama-shi (JP)

Correspondence Address: DLA PIPER RUDNICK GRAY CARY US, LLP, 2000 UNIVERSITY AVENUE, E. PALO ALTO, CA, 94303-2248, US

(21) Appl. No.: 10/769,146

(22) Filed: Jan. 29, 2004

(30) Foreign Application Priority Data
Oct. 29, 2003 (JP) 2003-369287

(51) Int. Cl. H01L 29/80; H01L 31/112; H01L 23/62

(52) U.S. Cl. 257/355; 257/358; 257/529

(57) ABSTRACT

A semiconductor integrated circuit includes an internal circuit having first and second external terminals, first and second fuse elements, each having first and second terminals, the first terminals of the first and second fuse elements being respectively connected to the first and second external terminals, and a discharge line connected to the second terminals of the first and second fuse elements and serving as an electrostatic discharge current path.

### CROSS-REFERENCE TO RELATED APPLICATIONS

This application is based upon and claims the benefit of priority from the prior Japanese Patent Application No. 2003-369287, filed Oct. 29, 2003, the entire contents of which are incorporated herein by reference.

### BACKGROUND OF THE INVENTION

1. Field of the Invention

The present invention relates to a semiconductor integrated circuit, and more particularly to a technology of protecting an element in the semiconductor integrated circuit from electrostatic discharge (hereinafter referred to as ESD).

2. Description of the Related Art

For example, in handling of a semiconductor integrated circuit before mounted on a circuit board, it is important to protect the semiconductor integrated circuit from ESD applied by a human body or another device to a signal terminal of the semiconductor integrated circuit. Protecting from ESD is achieved by using an ESD protection circuit network, in which ESD protection circuits are respectively connected to terminals of the semiconductor integrated circuit. Each ESD protection circuit comprises a protecting element (for example, a diode), which discharges static electricity to prevent it from reaching to a circuit to be protected in the semiconductor integrated circuit.

FIG. 8 shows an ESD protection circuit. A signal terminal I/O is connected to an input portion of an inverter circuit to be protected. A power supply terminal VDD is connected to a power supply connecting portion of the inverter circuit. A ground terminal VSS is connected to a ground connecting portion of the inverter circuit. A diode D1 is arranged in the reverse direction to forward direction between the power supply terminal VDD and the signal terminal I/O. A diode D2 is arranged in the reverse direction to forward direction between the signal terminal I/O and the ground terminal VSS.

In the ESD protection circuit, the diodes D1 and D2 are biased in the reverse direction during the normal operation, and do not influence the circuit operation.

On the other hand, when positive ESD is applied to the signal terminal I/O, electricity is discharged to the power supply terminal VDD as a forward current of the diode D1, and to the ground terminal VSS as a reverse current, which exceeds the breakdown voltage of the diode D2. Thus, ESD does not reach to the circuit to be protected.

When negative ESD is applied to the signal terminal I/O, electricity is discharged to the ground terminal VSS as a forward current of the diode D2, and to the power supply terminal VDD as a reverse current, which exceeds the breakdown voltage of the diode D1. Thus, ESD does not reach to the circuit to be protected.

When the protecting element is used as described above, the characteristic of the element inevitably imposes a limitation to the ESD protection circuit network. FIG. 9 shows a general characteristic of a protecting element. A protect voltage V_{OX} represents the breakdown voltage of the circuit to be protected. In this description, it is assumed that the circuit to be protected is formed of a MOS transistor. The protect voltage V_{OX} is lowered as the gate oxide film of the circuit to be protected is thinner. Therefore, in consideration of a snap back voltage Vₜ₁, a hold voltage Vₕ and an ON resistance Rₒₙ of the protecting element, the ESD protection circuit is designed such that the characteristic thereof falls within a protect-possible area, which is determined by the protect voltage V_{OX} and an ESD current I_{esd} compliant with the ESD standard.

It is assumed that the semiconductor integrated circuit, which performs ESD protecting by means of the protecting element, includes both an analog circuit and a digital circuit. In this case, before the semiconductor integrated circuit is mounted on a circuit board, an ESD path need be provided between the analog and digital circuits to perform ESD protecting therebetween. When the semiconductor integrated circuit is mounted on the circuit board, the analog circuit and the digital circuit need be electrically isolated to avoid noise. For this purpose, the ESD protection circuit is connected between the analog circuit and the digital circuit, thereby forming an ESD protection circuit network between the analog and digital circuits.

As related art of this type, Jpn. Pat. Appln. KOKAI Publication No. 2001-244338 discloses an example, in which a protecting element and a signal terminal are connected with a fuse element.

If the semiconductor integrated circuit, which performs ESD protecting by a protecting element, handles a high-frequency signal (for example, of several gigahertz), the parasitic capacitance of the protecting element may influence the circuit characteristic. In the system where the protecting element is used for ESD protecting, since the electrical connection between the signal terminal and the protecting terminal cannot be cut off, the parasitic capacitance of the protecting element appears in the signal terminal. Therefore, the characteristic of the high-frequency signal changes due to the parasitic capacitance.

In some type of ESD protection circuit network, the protecting elements are connected in series. FIG. 10 shows characteristics in the cases of using a protecting element 1, a protecting element 2 and protecting elements 1 and 2 connected in series. As can be seen from FIG. 10, in the case where the protecting elements 1 and 2 are connected in series, it is difficult to limit the characteristic in the protect-possible area. Further, since the related technology mentioned above also uses the protecting element, the characteristic of the protecting element need be taken into account.

Moreover, if the analog circuit and the digital circuit need be electrically isolated to avoid noise, an additional ESD protection circuit is required between the external terminal of the analog circuit and the external terminal of the digital circuit. Therefore, if the breakdown voltage of the circuit to be protected, connected the external terminals, is low, ESD protecting is difficult.

Furthermore, the protecting element cannot be downsized, although the area of the circuit can be reduced as the LSI has become finer. Therefore, when the protecting element is used, the ratio of the area of the ESD protection circuit to that of the overall circuit is inevitably large.

### BRIEF SUMMARY OF THE INVENTION

According to a first aspect of the present invention, there is provided a semiconductor integrated circuit including: an internal circuit having first and second external terminals; first and second fuse elements, each having first and second terminals, the first terminals of the first and second fuse elements being respectively connected to the first and second external terminals; and a discharge line connected to the second terminals of the first and second fuse elements and serving as an electrostatic discharge current path.

According to a second aspect of the present invention, there is provided a semiconductor integrated circuit including: an internal circuit having first and second external terminals; an electrostatic protecting circuit connected to the second external terminal; a fuse element having first and second terminals, the first terminal of the fuse element being connected to the first external terminal; and a discharge line connected to the electrostatic protecting circuit and the second terminal of the fuse element and serving as an electrostatic discharge current path.

According to a third aspect of the present invention, there is provided a semiconductor integrated circuit including: an internal circuit having first, second and third external terminals; a fuse element having first and second terminals, the first terminal of the fuse element being connected to the first external terminal; first and second electrostatic protecting circuits respectively connected to the second and third external terminals; a first discharge line connected to the first and second electrostatic protecting circuits and serving as an electrostatic discharge current path; and a second discharge line connected to the second terminal of the fuse element and the second external terminal and provided to keep the first and second external terminals at substantially the same potential.

According to a fourth aspect of the present invention, there is provided a semiconductor integrated circuit including: a digital circuit having a first external terminal; a first electrostatic protecting circuit connected to the first external terminal; a first discharge line connected to the first electrostatic protecting circuit and serving as an electrostatic discharge current path; an analog circuit having a second external terminal; a second electrostatic protecting circuit connected to the second external circuit; a second discharge line connected to the second electrostatic protecting circuit and serving as an electrostatic discharge current path; and a fuse element connected between the first and second discharge lines and serving as an electrostatic discharge current path of the digital and analog circuits.

### BRIEF DESCRIPTION OF THE SEVERAL VIEWS OF THE DRAWING

FIG. 1 is a diagram showing a main part of a semiconductor integrated circuit 1 according to a first embodiment of the present invention.

FIG. 2 is a diagram showing examples of maximum currents of ESD compliant with the ESD standard.

FIG. 3 is a circuit diagram of a capacity discharge circuit to perform an ESD test.

FIG. 4 is a diagram showing a main part of a semiconductor integrated circuit 10 according to a second embodiment of the present invention.

FIG. 5 is a diagram showing a main part of a semiconductor integrated circuit 20 according to a third embodiment of the present invention.

FIG. 6 is a diagram showing a main part of a semiconductor integrated circuit 30 according to a fourth embodiment of the present invention.

FIG. 7 is a diagram showing a main part of a semiconductor integrated circuit 40 according to a fifth embodiment of the present invention.

FIG. 8 is a diagram showing an ESD protection circuit.

FIG. 9 is a diagram showing a general characteristic of a protecting element.

FIG. 10 is a diagram showing characteristics in the cases of using a protecting element 1, a protecting element 2 and protecting elements 1 and 2 connected in series.

### DETAILED DESCRIPTION OF THE INVENTION

Embodiments of the present invention will now be described with reference to the accompanying drawings.

### First Embodiment

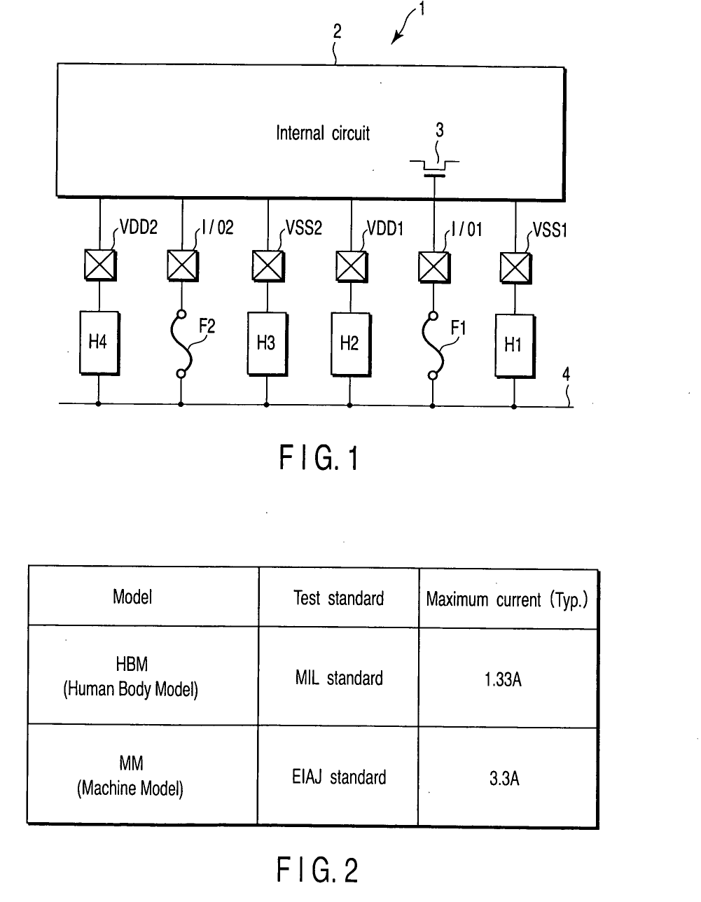

FIG. 1 is a diagram showing a main part of a semiconductor integrated circuit 1 according to the first embodiment of the present invention.

The semiconductor integrated circuit 1 has an internal circuit 2, which is to be protected against ESD. A plurality of external terminals are connected to the internal circuit 2. VSS1 and VSS2 denote ground terminals. The terminals VSS1 and VSS2 are connected to a power supply line having the ground potential. VDD1 and VDD2 denote power supply terminals. The power supply terminals VDD1 and VDD2 are connected to a power supply line having, for example, the highest potential. I/O1 and I/O2 denote signal terminals, through which signals are input or output.

The ground terminal VSS1, the power supply terminal VDD1, the ground terminal VSS2 and the power supply terminal VDD2 are respectively connected to first terminals of ESD protection circuits H1, H2, H3 and H4. Each of the ESD protection circuits H1 to H4 is formed of, for example, two diodes.

The signal terminals I/O1 and I/O2 are respectively connected to first terminals of fuse elements F1 and F2. Second terminals of the ESD protection circuits and second terminals of the fuse elements F1 and F2 are connected to a discharge line 4. The signal terminal I/O1 is connected to the gate of a MOS transistor 3 provided in the internal circuit 2.

In the semiconductor integrated circuit 1 configured as described above, an ESD protecting path is formed between any two of the external terminals. For example, assume that ESD is applied to the signal terminal I/O1 and the ground terminal VSS2 is grounded. In this case, an ESD current is discharged through the fuse element F1, the discharge line 4, the ESD protection circuit H3 and the ground terminal VSS2. Therefore, it is possible to protect the internal circuit 2 from ESD. The same applies to any other external circuit.

The resistance values of the fuse element F1 and the discharge line 4 are set to satisfy the following relationship:
V_{OX}>(Rₘ+Rₓ)×I_{esd}
where V_{OX} represents the breakdown voltage of the circuit to be protected, which is connected to the signal terminal I/O1 (the breakdown voltage of the gate oxide film of the MOS transistor 3 in this embodiment), Rₘ represents the resistance value of the wiring in an electrostatic discharge path between the signal terminal I/O1 and any of the external terminals, Rₓ represents the resistance value of all fuse elements arranged in the electrostatic discharge path between the signal terminal I/O1 and any of the external terminals, and I_{esd} represents the maximum current of ESD compliant with the ESD standard. FIG. 2 is a diagram showing examples of maximum currents of ESD compliant with the ESD standard.

When the resistance values of the fuse element F1 and the discharge line 4 are set to satisfy the above formula, if an ESD current flows from, for example, the signal terminal I/O1 to the ground terminal VSS2, the voltage at the signal terminal I/O1 is lower than the breakdown voltage V_{OX}. Therefore, the gate oxide film of the MOS transistor 3 is prevented from breakdown. The same applies to the other fuse element.

When the semiconductor integrated circuit 1 is, for example, mounted on a circuit board, the fuse elements F1 and F2 are electrically cut off. As a result, the input capacitances to the signal terminals I/O1 and I/O2 can be drastically reduced. Therefore, even if the signal terminal I/O1 handles a high-frequency signal (for example, of several gigahertz), the characteristic of the high-frequency signal will not change. Consequently, the high-frequency signal can be accurately processed.

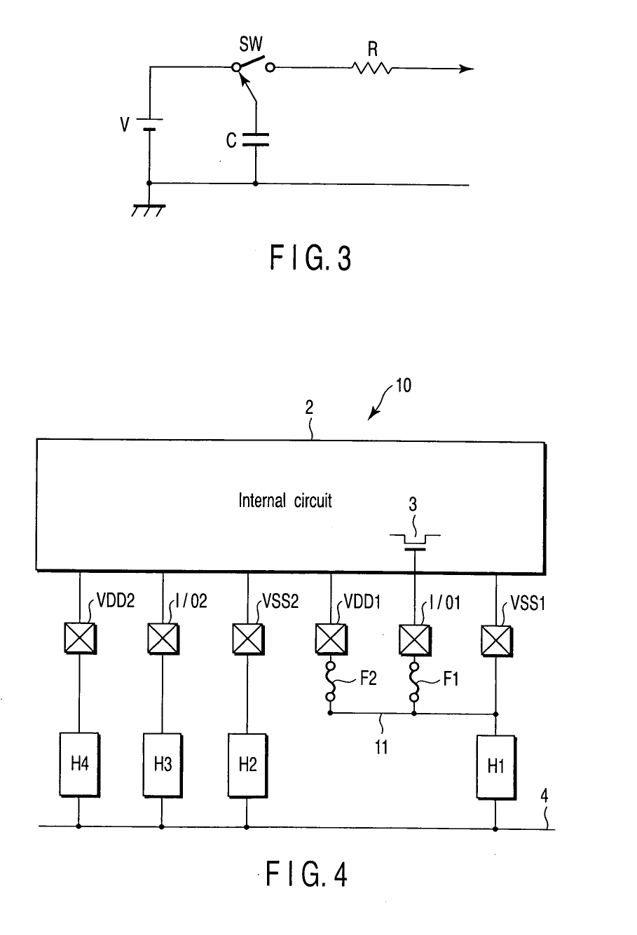

Break of the fuse elements F1 and F2 will be described below. FIG. 3 is a circuit diagram of a capacity discharge circuit to perform an ESD test. V denotes a DC voltage source, C denotes an equivalent capacitor, R denotes an equivalent resistor, and SW denotes a switch which switches charge and discharge of the equivalent capacitor C.

It is assumed that the resistor R of the resistance 0 Ω and the capacitor C of the capacitance 200 pF are used to test an equivalent operation of the case where ESD is applied from a device (Machine Model). On the other hand, it is assumed that the resistor R of the resistance 1.5 Ω and the capacitor C of the capacitance 100 pF are used to test an equivalent operation of the case where ESD is applied from a human body (Human Body Model).

In the Machine Model, if the internal circuit 2 is resistant to the voltage of 200V, there is no problem of damage in the internal circuit 2 due to ESD. In the Human Body Model, if the internal circuit 2 is resistant to the voltage of 2000V, there is no problem of damage in the internal circuit 2 due to ESD.

Electrostatic energy in the Machine Model is 4 μJ, when the voltage is 200V. Electrostatic energy in the Human Model is 200 μJ, when the voltage is 2000V. In the Human Model, since energy is consumed in the resistor R, all the static energy is not applied to the internal circuit 2.

Therefore, it is sufficient for the fuse element F1 or F2 to have such a resistance as not to break at an energy level of 200 μJ at the maximum. The number of ESD tests for the semiconductor integrated circuit 1 is 100 or less, in consideration of the number of terminals of the circuit 1. Therefore, the fuse element F1 or F2 has a resistance so as not to break even when energy of the level of 200 μJ is applied 100 times or less.

As described above, when the semiconductor integrated circuit 1 is mounted on, for example, a circuit board, the fuse elements F1 and F2 are electrically cut off. For example, a direct current is used to break the fuse elements F1 and F2. The value of the direct current is large enough to break the fuse elements in seconds. The present inventor discovered through experiments that the fuse elements used in this invention could be broken by a current of 30 mA or smaller. Further, the fuse elements were broken by supplying the current of the above value within 20 seconds. Thus, the fuse elements can easily be broken with a direct current of the above value.

As has been described, according to this embodiment, the power supply terminals of the external terminals, connected to the internal circuit 2 of the semiconductor integrated circuit 1, are connected to the ESD protection circuits. On the other hand, the signal terminals of the external terminals are connected to the fuse elements. The ESD protection circuits and the fuse elements are connected by the discharge line 4.

Thus, in this embodiment, the ESD protection circuits are not connected to a signal terminal which handles a high frequency signal. Therefore, a change in circuit characteristic, due to parasitic capacitance, can be prevented.

Further, the resistance values of the fuse element and the discharge line 4 in the electrostatic discharge path are set to satisfy the relationship represented by the above formula. Therefore, the gate oxide film of the MOS transistor 3, to be protected against ESD, is prevented from breakdown.

Furthermore, the fuse element used in this embodiment is not broken even if energy at the maximum assumable level of 200 μJ is applied. Therefore, the internal circuit 2 can reliably be protected against ESD.

Moreover, the fuse element used in this embodiment is not broken even if energy of the aforementioned level is applied 100 times, which is the maximum number assumable in ESD experiments. Therefore, the fuse element is not broken during the ESD test.

Furthermore, since the fuse element has a small circuit area relative to the ESD protection circuit, the circuit area of the semiconductor integrated circuit 1 can be reduced.

### Second Embodiment

In the second embodiment, an external terminal connected to an ESD protection circuit is connected to a signal terminal through a discharge line and a fuse element. The external terminal and the signal terminal are kept at substantially the same potential.

FIG. 4 is a diagram showing a main part of a semiconductor integrated circuit 10 according to the second embodiment of the present invention. The same parts and structures as those shown in FIG. 1 are identified by the same reference numerals, and detailed descriptions thereof are omitted.

A first terminal of an ESD protection circuit H1 is connected to a ground terminal VSS1. A first terminal of a fuse element F1 is connected to a signal terminal I/O1. A first terminal of a fuse element F2 is connected to a power supply terminal VDD1. The ground terminal VSS1 is connected to second terminals of the fuse elements F1 and F2 by a discharge line 11. The terminal connected to the ESD protection circuit H1 is not limited to the ground terminal VSS1 but may be the power supply terminal VDD1. The gate of the MOS transistor 3 in the internal circuit 2 is connected to the signal terminal I/O1.

In the semiconductor integrated circuit 10 thus configured, the ground terminal VSS1, the signal terminal I/O1 and the power supply terminal VDD1 are kept at substantially the same potential. In this embodiment, it is assumed that ESD is applied to the signal terminal I/O1 and the ground terminal VSS2 is grounded. In this case, an ESD current is discharged through the fuse element F1, the discharge line 11, the ESD protection circuit H1, the discharge line 4, the ESD protection circuit H2 and the ground terminal VSS2. Therefore, the internal circuit 2 is protected from ESD. The same applies to the case in which ESD is applied to the power supply terminal VDD1 and, for example, the ground terminal VSS is grounded.

The resistance values of the fuse element F1 and the discharge lines 4 and 11 are set to satisfy the following relationship as in the first embodiment:
V_{OX}>(Rₘ+Rₓ)×I_{esd}

When the resistance values of the fuse element F1 and the discharge line 4 are set to satisfy this formula, if an ESD current flows from, for example, the signal terminal I/O1 to the ground terminal VSS2, the voltage at the signal terminal I/O1 is lower than the breakdown voltage V_{OX}. Therefore, the gate oxide film of the MOS transistor 3 is prevented from breakdown.

When the semiconductor integrated circuit 10 is, for example, mounted on a circuit board, the fuse elements F1 and F2 are electrically cut off. As a result, the input capacitance to the signal terminal I/O1 can be drastically reduced. Therefore, even if the signal terminal I/O1 handles a high-frequency signal (for example, of several gigahertz), the characteristic of the high-frequency signal will not change. Consequently, the high-frequency signal can be processed accurately. In addition, the ground terminal VSS2, the signal terminal I/O1 and the power supply terminal VDD1 can be electrically isolated.

Thus, in this embodiment, the ESD protection circuits are not connected to a signal terminal which handles a high frequency signal. Therefore, a change in circuit characteristic, due to parasitic capacitance, can be prevented.

Further, the resistance values of the fuse element and the discharge lines 11 and 4 in the electrostatic discharge path are set to satisfy the relationship represented by the above formula. Therefore, the gate oxide film of the MOS transistor 3, to be protected against ESD, is prevented from breakdown.

Moreover, only one ESD protection circuit H1 is used for the three external terminals: the power supply terminal VDD1, the signal terminal I/O1 and the ground terminal VSS1. Therefore, the number of ESD protection circuits can be drastically reduced. Accordingly, the cost can be reduced, and the workload for circuit design can be lightened.

Furthermore, since the fuse element has a small circuit area relative to the ESD protection circuit, the circuit area of the semiconductor integrated circuit 10 can be reduced.

### Third Embodiment

A third embodiment is a semiconductor integrated circuit configured to reliably perform ESD protecting without using an ESD protection circuit.

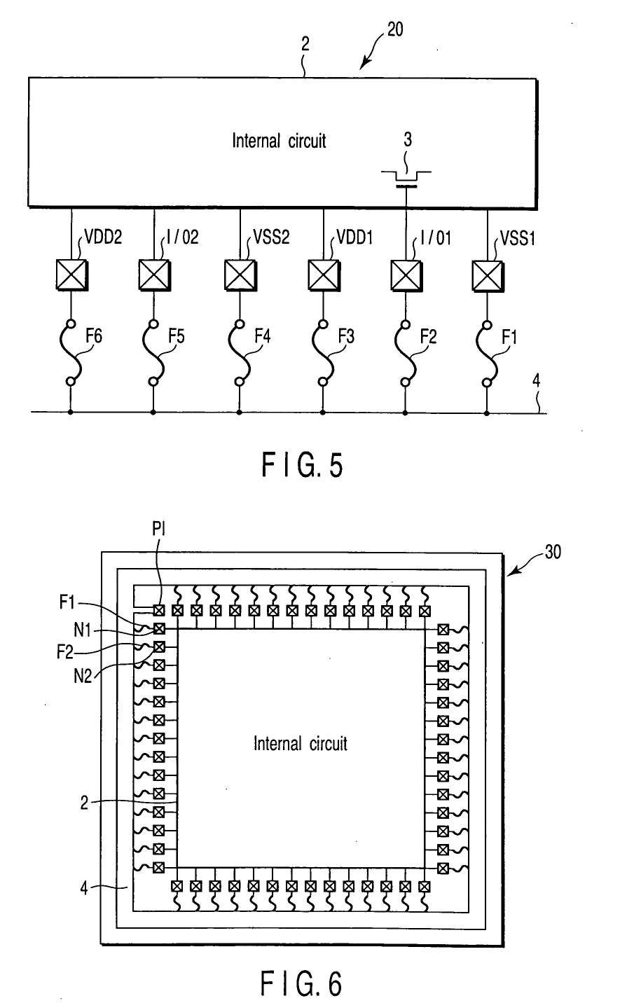

FIG. 5 is a diagram showing a main part of a semiconductor integrated circuit 20 according to the third embodiment of the present invention. The same parts and structures as those shown in FIG. 1 are identified by the same reference numerals, and detailed descriptions thereof are omitted.

A ground terminal VSS1, a signal terminal I/O1, a power supply terminal VDD1, a ground terminal VSS2, a signal terminal I/O2 and a power supply terminal VDD2 are respectively connected to first terminals of fuse elements F1 to F6. A discharge line 4 is connected to second terminals of the fuse elements F1 to F6. The signal terminal I/O1 is connected to the gate of a MOS transistor 3 provided in the internal circuit 2.

In the semiconductor integrated circuit 20 configured as described above, an ESD protecting path is formed between any two of the external terminals. Every ESD protecting path passes through two fuse elements and the discharge line 4. For example, assume that ESD is applied to the signal terminal I/O1 and the ground terminal VSS2 is grounded. In this case, an ESD current is discharged through the fuse element F2, the discharge line 4, the fuse element 4 and the ground terminal VSS2. Therefore, it is possible to protect the internal circuit 2 from ESD. The same applies to any of the other external terminals.

The resistance values of the fuse elements F1 to F6 and the discharge line 4 are set to satisfy the following relationship as in the first embodiment:
V_{OX}>(Rₘ+Rₓ)×I_{esd}

When the resistance values of the fuse element F1 and the discharge line 4 are set to satisfy this formula, if an ESD current flows from, for example, the signal terminal I/O1 to the ground terminal VSS2, the voltage at the signal terminal I/O1 is lower than the breakdown voltage V_{OX}. Therefore, the gate oxide film of the MOS transistor 3 is prevented from breakdown. The same applies to the other fuse element.

When the semiconductor integrated circuit 20 is, for example, mounted on a circuit board, the fuse elements F1 to F6 are electrically cut off. As a result, the internal circuit 2 cannot malfunction during the normal operation. In addition, since no ESD protection circuit is used, the operation of the internal circuit 2 cannot be adversely affected by a leak current from an ESD protection circuit or parasitic capacitance generated in an ESD protection circuit.

Thus, according to this embodiment, since no ESD protection circuit is connected to any signal terminal that handles a high-frequency signal, a change in circuit characteristic, due to parasitic capacitance, can be prevented.

Further, the resistance values of the two fuse elements and the discharge line 4 in the electrostatic discharge path are set to satisfy the relationship represented by the above formula. Therefore, the gate oxide film of the MOS transistor 3, to be protected against ESD, is prevented from breakdown.

Since the semiconductor integrated circuit 20 has no ESD protection circuit, it is unnecessary to take the characteristic of an ESD protection circuit into consideration. Therefore, the workload for circuit design can be lightened.

Furthermore, since no ESD protection circuit is used, the circuit area of the semiconductor integrated circuit 20 can be reduced.

### Fourth Embodiment

FIG. 6 is a diagram showing a semiconductor integrated circuit 30 according to the fourth embodiment of the present invention. The same parts and structures as those shown in FIG. 1 are identified by the same reference numerals, and detailed descriptions thereof are omitted.

A discharge line 4 surrounds the internal circuit 2. A plurality of external terminals N1 to Nn are connected to the internal circuit 2. First terminals of fuse elements F1 to Fn are respectively connected to the external terminals N1 to Nn. Second terminals of the fuse elements F1 to Fn are connected to the discharge line 4. The semiconductor integrated circuit 30 has a power input terminal PI. The power input terminal PI is connected to the discharge line 4 alone.

In the semiconductor integrated circuit 30 configured as described above, an ESD protecting path is formed between any two of the external terminals. The semiconductor integrated circuit 30 has no ESD protection circuit. Since it is only necessary to consider the size of a fuse element that can be resistant to ESD and the width of the discharge line 4 that can be resistant to ESD, the circuit area of the semiconductor integrated circuit 30 can be reduced.

Generally, in the case of a 5 mm square chip having 256 terminals, the area of the ESD protection circuit occupies 14% of the overall chip. However, in this embodiment, assuming that the length of the fuse element is 10 μm and the width of the discharge line 4 is 40 μm, the area occupied by the fuse elements F1 to Fn and the discharge line 4 can be restricted to about 4% of the overall chip. The other effects of the fourth embodiment are the same as those of the third embodiment.

How to break the fuse element F1 will now be described. First, the external terminal N1 is externally fixed to the ground potential. Then, a direct current is externally applied as a power to the power input terminal PI. The value of the direct current is large enough to break the fuse element F1 in seconds. The present inventor discovered through experiments that the fuse elements used in this embodiment could be broken by a current of 30 mA or smaller. Therefore, the fuse element F1 can easily be broken. The same applies to the other fuse element. Instead of the direct current, a direct voltage may be externally applied to the power input terminal PI as a power.

As has been described, in this embodiment, the fuse elements F1 to Fn are respectively connected to the external terminals N1 to Nn connected to the internal circuit 2. The fuse elements F1 to Fn are connected to the discharge line 4. Further, this embodiment has the power input terminal PI to externally supply a direct current. The power input terminal PI is connected to the discharge line 4.

Thus, according to this embodiment, since the semiconductor integrated circuit 30 has no ESD protection circuit, the circuit area of the semiconductor integrated circuit 30 can be reduced.

Moreover, the fuse element can easily be broken by applying a direct current to the power input terminal PI, and fixing, to the ground potential, the external terminal connected to the fuse element to be broken.

### Fifth Embodiment

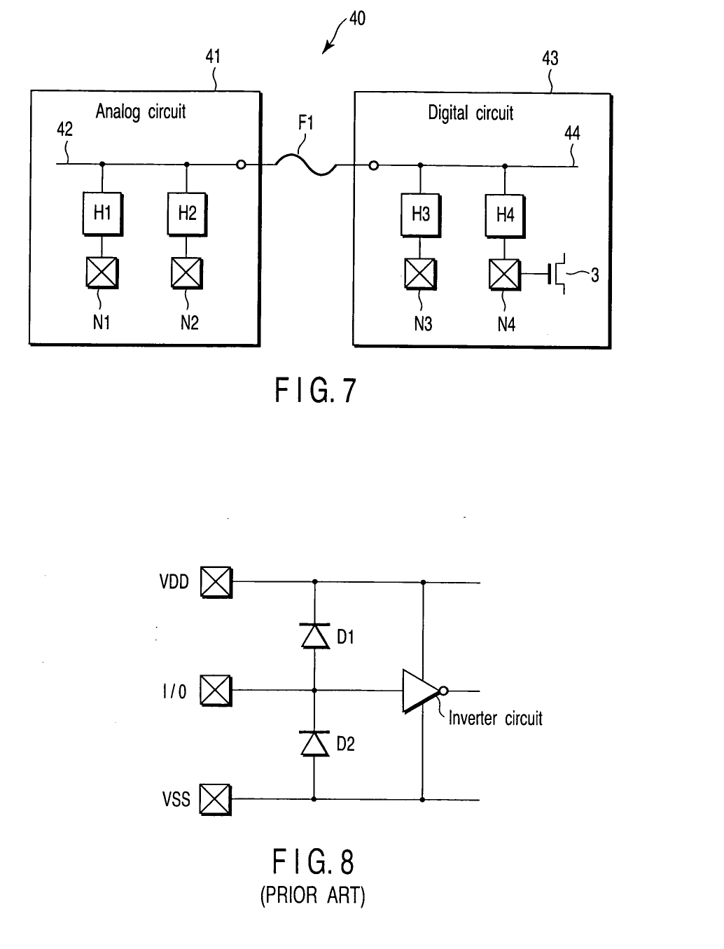

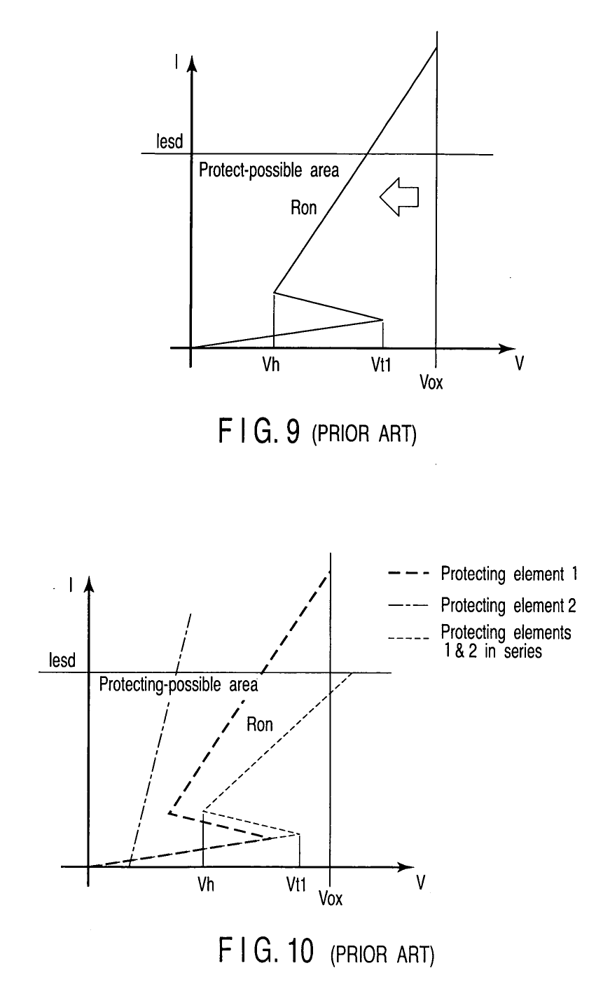

FIG. 7 is a diagram showing a main part of a semiconductor integrated circuit 40 according to the fifth embodiment of the present invention. The same parts and structures as those shown in FIG. 1 are identified by the same reference numerals, and detailed descriptions thereof are omitted.

The semiconductor integrated circuit 40 has an analog circuit 41 and a digital circuit 43. The analog circuit 41 has external terminals N1 and N2. The external terminals N1 and N2 are respectively connected to analog elements (not shown) in the analog circuit 41. The external terminals N1 and N2 are respectively connected to first terminals of ESD protection circuits H1 and H2. Second terminals of the ESD protection circuits H1 and H2 are connected to the discharge line 42.

The digital circuit 43 has external terminals N3 and N4. The external terminals N3 and N4 are respectively connected to digital elements (not shown) in the digital circuit 43. The external terminals N3 and N4 are respectively connected to first terminals of the ESD protection circuits H3 and H4. Second terminals of the ESD protection circuits H3 and H4 are connected to the discharge line 44.

The discharge lines 42 and 44 are connected to each other by a fuse element F1. Thus, the analog circuit 41 and the digital circuit 43 form an ESD path.

In the semiconductor integrated circuit 40 configured as described above, an ESD protecting path is formed between any two external terminals in the analog circuit 41. An ESD protecting path is also formed between any two external terminals in the digital circuit 43. Further, an ESD protecting path is formed between any of the external terminals in the analog circuit 41 and any of the external terminals in the digital circuit 43.

For example, assume that ESD is applied to the external terminal N4 and the external terminal N2 is grounded. In this case, an ESD current is discharged through the ESD protection circuit H4, the discharge line 44, the fuse element F1, the discharge line 42, the ESD protection circuit H2 and the external terminal N2. Therefore, it is possible to protect the digital element in the digital circuit 43 from ESD. The same applies to any of the other external terminals.

The resistance values of the fuse element F1 and the discharge lines 42 and 44 are set to satisfy the following relationship:
V_{OX}>(Rₘ+Rₓ)×I_{esd}
where V_{OX} represents the breakdown voltage of the circuit to be protected, which is connected to the external terminal N4 (the breakdown voltage of the gate oxide film of the MOS transistor 3 in this embodiment), Rₘ represents the resistance value of the wiring in an electrostatic discharge path between the external terminals N4 and N2, Rₓ represents the resistance value of the fuse element F1, and I_{esd} represents the maximum current of ESD compliant with the ESD standard.

When the resistance values of the fuse element F1 and the discharge lines 42 and 44 are set to satisfy the above formula, if an ESD current flows from the external terminal N4 to the external terminal N2, the voltage at the external terminal N4 is lower than the breakdown voltage V_{OX}. Therefore, the gate oxide film of the MOS transistor 3 is prevented from breakdown.

When the semiconductor integrated circuit 40 is, for example, mounted on a circuit board, the fuse element F1 is electrically cut off. As a result, the analog circuit 41 and the digital circuit 43 can be electrically isolated. Therefore, it is possible to prevent transmission of noise generated from, for example, the digital circuit 43, to the analog circuit 41.

As has been described, in this embodiment, the semiconductor integrated circuit 40 has the analog circuit 41 and the digital circuit 43, each having an ESD protection circuit network. To form the ESD path between the analog circuit 41 and the digital circuit 43, the discharge line 42 of the analog circuit 41 and the discharge line 44 of the digital circuit 43 are connected by the fuse element F1.

Thus, in this embodiment, the ESD path can be formed between the analog circuit 41 and the digital circuit 43.

When the semiconductor integrated circuit 40 is, for example, mounted on a circuit board, the fuse element F1 is electrically cut off, so that the analog circuit 41 and the digital circuit 43 can be electrically isolated.

Further, since the resistance values of the fuse element F1 and the discharge lines 42 and 44 are set to satisfy the relationship represented by the above formula, the gate oxide film of the MOS transistor 3, to be protected against ESD, is prevented from breakdown.

Moreover, the number of ESD protection circuits, between any external terminal in the analog circuit 41 and any external terminal in the digital circuit 43, can be less by one. Consequently, the workload for circuit design relating to the characteristics of ESD protection circuits can be reduced.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor integrated circuit comprising:
an internal circuit having first and second external terminals;
first and second fuse elements, each having first and second terminals, the first terminals of the first and second fuse elements being respectively connected to the first and second external terminals; and
a discharge line connected to the second terminals of the first and second fuse elements and serving as an electrostatic discharge current path.

2. The semiconductor integrated circuit according to claim 1, wherein:
the internal circuit further has a MOS transistor having a gate connected to the first external terminal; and
each of the first and second fuse elements has a resistance value that satisfies:
V_{OX}>(Rₘ+Rₓ)×I_{esd}
where V_{OX} represents a breakdown voltage of a gate oxide film of the MOS transistor, Rₘ represents a wire resistance value in the electrostatic discharge current path between the first and second external terminals, Rₓ represents a resistance value of all fuse elements arranged in the electrostatic discharge current path between the first and second external terminals, and I_{esd} represents a value of an electrostatic discharge current.

3. The semiconductor integrated circuit according to claim 1, wherein the fuse elements remain firm even when energy of 200 μJ is applied thereto.

4. The semiconductor integrated circuit according to claim 1, wherein the fuse elements remain firm even when energy of 200 μJ is applied thereto but break when a direct current of 30 mA is applied thereto within 20 seconds.

5. The semiconductor integrated circuit according to claim 1, wherein the fuse elements are electrically disconnected when the semiconductor integrated circuit is mounted on a circuit board.

6. A semiconductor integrated circuit comprising:
an internal circuit having first and second external terminals;
an electrostatic protecting circuit connected to the second external terminal;
a fuse element having first and second terminals, the first terminal of the fuse element being connected to the first external terminal; and
a discharge line connected to the electrostatic protecting circuit and the second terminal of the fuse element and serving as an electrostatic discharge current path.

7. The semiconductor integrated circuit according to claim 6, wherein:
the internal circuit further has a MOS transistor having a gate connected to the first external terminal; and
the fuse element has a resistance value that satisfies:
V_{OX}>(Rₘ+Rₓ)×I_{esd}
where V_{OX} represents a breakdown voltage of a gate oxide film of the MOS transistor, Rₘ represents a wire resistance value in the electrostatic discharge current path between the first and second external terminals, Rₓ represents a resistance value of the fuse element, and I_{esd} represents a value of an electrostatic discharge current.

8. The semiconductor integrated circuit according to claim 6, wherein the fuse element remains firm even when energy of 200 μJ is applied thereto.

9. The semiconductor integrated circuit according to claim 6, wherein the fuse element remains firm even when energy of 200 μJ is applied thereto but breaks when a direct current of 30 mA is applied thereto within 20 seconds.

10. The semiconductor integrated circuit according to claim 6, wherein the fuse element is electrically disconnected when the semiconductor integrated circuit is mounted on a circuit board.

11. A semiconductor integrated circuit comprising:
an internal circuit having first, second and third external terminals;
a fuse element having first and second terminals, the first terminal of the fuse element being connected to the first external terminal;
first and second electrostatic protecting circuits respectively connected to the second and third external terminals;
a first discharge line connected to the first and second electrostatic protecting circuits and serving as an electrostatic discharge current path; and
a second discharge line connected to the second terminal of the fuse element and the second external terminal and provided to keep the first and second external terminals at substantially the same potential.

12. The semiconductor integrated circuit according to claim 11, wherein:
the internal circuit further has a MOS transistor having a gate connected to the first external terminal; and
the fuse element has a resistance value that satisfies:
V_{OX}>(Rₘ+Rₓ)×I_{esd}
where V_{OX} represents a breakdown voltage of a gate oxide film of the MOS transistor, Rₘ represents a wire resistance value in the electrostatic discharge current path between the first and second external terminals or between the first and third external terminals, Rₓ represents a resistance value of the fuse element, and I_{esd} represents a value of an electrostatic discharge current.

13. The semiconductor integrated circuit according to claim 11, wherein the fuse element remains firm even when energy of 200 μJ is applied thereto.

14. The semiconductor integrated circuit according to claim 11, wherein the fuse element remains firm even when energy of 200 μJ is applied thereto but breaks when a direct current of 30 mA is applied thereto within 20 seconds.

15. The semiconductor integrated circuit according to claim 11, wherein the fuse element is electrically disconnected when the semiconductor integrated circuit is mounted on a circuit board.

16. A semiconductor integrated circuit comprising:
a digital circuit having a first external terminal;
a first electrostatic protecting circuit connected to the first external terminal;
a first discharge line connected to the first electrostatic protecting circuit and serving as an electrostatic discharge current path;
an analog circuit having a second external terminal;
a second electrostatic protecting circuit connected to the second external circuit;
a second discharge line connected to the second electrostatic protecting circuit and serving as an electrostatic discharge current path; and
a fuse element connected between the first and second discharge lines and serving as an electrostatic discharge current path of the digital and analog circuits.

17. The semiconductor integrated circuit according to claim 16, wherein:
the digital circuit further has a MOS transistor having a gate connected to the first external terminal; and
the fuse element has a resistance value that satisfies:
V_{OX}>(Rₘ+Rₓ)×I_{esd}
where V_{OX} represents a breakdown voltage of a gate oxide film of the MOS transistor, Rₘ represents a wire resistance value in the electrostatic discharge current path between the first and second external terminals, Rₓ represents a resistance value of the fuse element, and I_{esd} represents a value of an electrostatic discharge current.

18. The semiconductor integrated circuit according to claim 16, wherein the fuse element remains firm even when energy of 200 μJ is applied thereto.

19. The semiconductor integrated circuit according to claim 16, wherein the fuse element remains firm even when energy of 200 μJ is applied thereto but breaks when a direct current of 30 mA is applied thereto within 20 seconds.

20. The semiconductor integrated circuit according to claim 16, wherein the fuse element is electrically disconnected when the semiconductor integrated circuit is mounted on a circuit board.
